(19) United States
(12) Patent Application Publication
(10) Pub. No.: US 2016/0165766 A1
(43) Pub. Date: Jun. 9, 2016

(54) METHOD FOR MAKING ELECTROMAGNETIC WAVE SHIELDING MATERIAL

(71) Applicant: NATIONAL CHUNG SHAN INSTITUTE OF SCIENCE AND TECHNOLOGY, Longtan Township (TW)

(72) Inventors: YEN-CHUNG CHEN, LONGTAN TOWNSHIP (TW); SUNG-YING TSAI, LONGTAN TOWNSHIP (TW); HUNG-FANG HUANG, DAXI TOWNSHIP (TW); JEN-BING WON, PINGZHEN CITY (TW); MING-DER GER, DAXI TOWNSHIP (TW)

(21) Appl. No.: 14/558,847

(22) Filed: Dec. 3, 2014

(51) Int. Cl. H05K 9/00

(52) U.S. Cl. CPC H05K 9/0081

(57) ABSTRACT

A method for making an electromagnetic wave shielding material comprises the steps of (a) mixing ternary Fe—Al—Si alloy powders and a solvent to prepare a Fe—Al—Si solution; (b) adding an acid in the Fe—Al—Si solution to release Fe ions through a dissolution reaction; (c) adding copper chloride powders in the Fe—Al—Si solution; (d) adding a lye in the Fe—Al—Si solution to induce a displacement reaction; (e) adding a silane coupling agent in the Fe—Al—Si solution; (f) placing the Fe—Al—Si solution in a microwave reactor to accelerate the displacement reaction; (g) producing a quaternary Cu—Fe—Al—Si alloy after the displacement reaction of the Fe—Al—Si solution, thereby forming a quaternary Cu—Fe—Al—Si alloy solution, which proceeding with a solid-liquid separation and a drying treatment to obtain an electromagnetic wave shielding material composed of quaternary Cu—Fe—Al—Si alloy in solid powders.

### FIELD OF TECHNOLOGY

The present invention relates to an electromagnetic wave absorption technique and, more particularly, to a method for making an electromagnetic wave shielding material.

### BACKGROUND

The waveform and energy required by the system and the circuit are called “signal”, and the signal that is not required by the system and the circuit is called “noise”. When the energy of the noise is excessive or when the noise damages the functions of the system, the noise is called interference. If the interference is in the form of electromagnetic energy or a waveform, then the interference is called electromagnetic interference (EMI). The action or device that protects the system or the circuit from EMI is called electromagnetic shielding (EMS). When the system or the circuit is protected by EMS and free of EMI issues, it is called electromagnetic compatibility (EMC).

In recent years, as the rapid development of wireless communication, regulations and standards set all over the world are increasingly strict. Since the functions of modern electronic products are more and more powerful and the operation speed is faster and faster, the electronic circuits are denser and more complicated than before. Therefore, EMI and EMC issues have become the main challenge in design. All the Bluetooth, GPS, and RFID are key techniques in all kinds of applications. Currently, the electromagnetic wave shielding material mainly includes metal sheets, metal foam, metal conductive coatings, amorphous metal materials, metal filled composite materials, and other types of materials.

The metal sheet shielding materials are generally divided into two categories: 1. good conductor type shielding material that is often used for shielding in electrostatic field and high and low frequency electromagnetic fields due to its high electric conductivity, such as copper, aluminum, nickel, etc.; 2. ferromagnetic type shielding material that is often used for shielding in low frequency fields but not suitable for high frequency electromagnetic fields due to its high magnetic permeability and low electric conductivity, such as iron, silicon steel alloy, etc.

Metal foam is a porous material composed of metal skeleton and interconnecting air-filled pores, such as nickel metal foam, copper-nickel metal foam, and aluminum metal foam, etc. Metal foam has been applied to the manufacture of heat dissipation structures of precision instruments due to its characteristics of light weight, high specific strength, good electromagnetic shielding performance, etc. The shielding mechanism of metal foam is attenuation of electromagnetic wave through multiple reflections and absorption within the pores. However, metal foam has the following drawbacks: 1. Metal foam will have little contribution to the electromagnetic shielding performance of the material once its density exceeds a critical value. 2. The smaller the pore size of metal foam, the better the shielding performance. However, in order to achieve the favorable pore size, the preparation of metal foam material will become more complex. 3. Metal foam has poor mechanics properties so that it cannot be used as the structural material alone.

The metal conductive coating is made from well dispersed fine metal powders having good electric conduction performance. The metal conductive coatings that are commonly used include silver-based, nickel-based and copper-based conductive coatings. The silver-based conductive coating has good electric conduction performance, but is expensive. The copper-based conductive coating has better electric conduction performance and moderate price, but it is chemically active and thus unstable in electric conduction due to its easily oxidized surface. The nickel-based conductive coating has better shielding effect in medium frequency band, but worse shielding effect in low and high frequency bands. Research has showed the electromagnetic shielding performance of the coating of fine nickel powders admixed with metal fibers and indicates that the shielding effect in low frequency band (9 kHz-500 MHz) is improved after the few metal fibers are added.

The metal filled composite material is generally composed of polymer matrix, electrically conductive fillers having good electric conduction performance, and some additives, and formed by extrusion molding, injection molding, or compression molding. The electromagnetic shielding effect of the fill type composite material mainly depends on the conductivity of the electrically conductive fillers as well as the extent of mutual lapping between the fillers. The electrically conductive fillers that are commonly used include metal-based fillers, such as metal sheet, metal fiber or powder, and metal-plated fillers, such as glass fiber, carbon fiber, carbon element, and the like. After the amount of the metal-based conductive filler in the polymer is increased to a certain level, certain structure of electrically conductive network can be created to exhibit effective electromagnetic shielding.

Both the length-to-diameter ratio and contact area of the metal fibers are larger than that of metal powders, so that at the same filling amount, it's easier for the metal fibers to form the electrically conductive network. Also, the metal fibers have higher conductivity and better electromagnetic shielding effect. After the filling amount of the metal-based conductive filler in the polymer is increased to a certain level, the metal-based conductive filler can form certain structure of conductive network and achieve effective electromagnetic shielding. Since high filling amount of conductive filler powder will deteriorate the mechanics properties of plastics, the electrically conductive plastic is generally manufactured using fibrous, spherical, reticular, dendritic or flake fillers. However, there exists a drawback that the shielding effect is susceptible to the uniformity of mixing.

The amorphous alloy has made great progress in magnetic device applications, such as transformers, switching power supplies, precision measuring instruments, magnetic heads, etc. The shielding performance of the amorphous alloy is better than conventional materials in that it utilizes the principle of magnetism bypass and guides the electromagnetic energy flow generated by the field source so that the electromagnetic energy flow won't flow into the protection zone. The amorphous alloy shielding materials can be classified into the amorphous structural shielding materials and the amorphous shielding coatings according to its form of application. The alloy-based materials commonly used in amorphous structural materials are iron-based, iron-nickel-based, and cobalt-based materials. The cobalt-based materials are widely used due to its high initial permeability, low high-frequency loss, high strength, and wear resistance. Furthermore, adding magnetic elements (such as iron, cobalt, and nickel) makes the product of the relative conductivity and permeability of the amorphous alloy increase, thereby facilitating the absorption of electromagnetic waves. The amorphous shielding coatings mainly employ the thermal spraying technique to form a coating of certain thickness on the surface of the plastic, steel sheet, permalloy, etc. in order to achieve the purpose of shielding and overcome the disadvantages of high stress, high cost, etc. when the conventional ferromagnetic materials are processed. Therefore, the amorphous alloy has high strength, high hardness, good corrosion resistance, excellent soft magnetization and magnetic shielding performance, but it has drawbacks, such as poor conductivity and electromagnetic shielding function that is scarcely comparable to the wave-absorbing effect.

### SUMMARY

In view of the shortcomings of the traditional techniques, the present invention provides a method for making an electromagnetic wave shielding material. The method utilizes microwave to accelerate the displacement reaction for preparing the quaternary Cu—Fe—Al—Si alloy powders. The principle of the method mainly aims at the surface of the Fe—Al—Si alloy, on which parts of Fe ions are dissolved and displaced by Cu atoms, thereby obtaining the electromagnetic wave shielding materials having various Fe/Cu ratios.

In order to improve the electromagnetic shielding effect of the amorphous shielding material in different frequency bands, the present invention discloses a method for preparing a novel electromagnetic wave shielding material. The electromagnetic wave shielding material manufactured by the method is amorphous, electrically conductive, and magnetically permeable, and can be used as a novel electromagnetic wave shielding material.

The present invention provides a method for making an electromagnetic wave shielding material. The method comprises the following steps: mixing ternary Fe—Al—Si alloy powders and a solvent to prepare a Fe—Al—Si solution; adding an acid in the Fe—Al—Si solution to release Fe ions through a dissolution reaction; adding copper chloride powders in the Fe—Al—Si solution; adding a lye in the Fe—Al—Si solution to induce a displacement reaction; adding a silane coupling agent in the Fe—Al—Si solution; placing the Fe—Al—Si solution in a microwave reactor to accelerate the displacement reaction; producing a quaternary Cu—Fe—Al—Si alloy after the displacement reaction of the Fe—Al—Si solution, thereby forming a quaternary Cu—Fe—Al—Si alloy solution, which proceeding with a solid-liquid separation and a drying treatment to obtain an electromagnetic wave shielding material in solid powders.

The present invention provides a method for making an electromagnetic wave shielding material. The method differs from the traditional technique in that the traditional technique mixes different ratios or kinds of solid powders directly, and thus the qualities of the powders produced are greatly dependent on the raw materials added and the manner of stirring. As a result, the uniformity and quality of the powder composed of multiple components are not easy to be controlled. In addition, the powder composed of multiple components and made by the traditional method is susceptible to uneven proportion such that the reproducibility of the electromagnetic shielding function is affected. The method for making an electromagnetic wave shielding material of the present invention utilizes the difference of the Cu—Fe reduction potential to dissolve the original surface of the Fe—Al—Si alloy matrix by the acid and release parts of Fe ions from the surface of the alloy first, and then replaces the dissolved Fe ions with Cu ions. Also, the microwave is utilized to accelerate the reaction and reduce the operation cost. Copper element may precipitate on the surface of the Fe—Al—Si alloy and form Cu—Fe—Al—Si powders. Therefore, the uniform quaternary alloy powder can be obtained and the issue of non-uniform powder composition is effectively solved. The present invention further adds the silane coupling agent during the reaction such that an anti-oxidation layer is formed on the surface of the Cu—Fe—Al—Si powders to provide improved corrosion resistance. The quaternary Cu—Fe—Al—Si alloy powder made by the present invention has permeability, and may be used not only for electromagnetic shielding but also for wave absorption.

Both the summary above and the detailed description and appended drawing below are for further illustrating the manners and means taken by the present invention to achieve the intended purposes as well as the efficacy of the present invention. Also, other objects and advantages of the present invention will be set forth in the following description and appended drawings.

### BRIEF DESCRIPTION

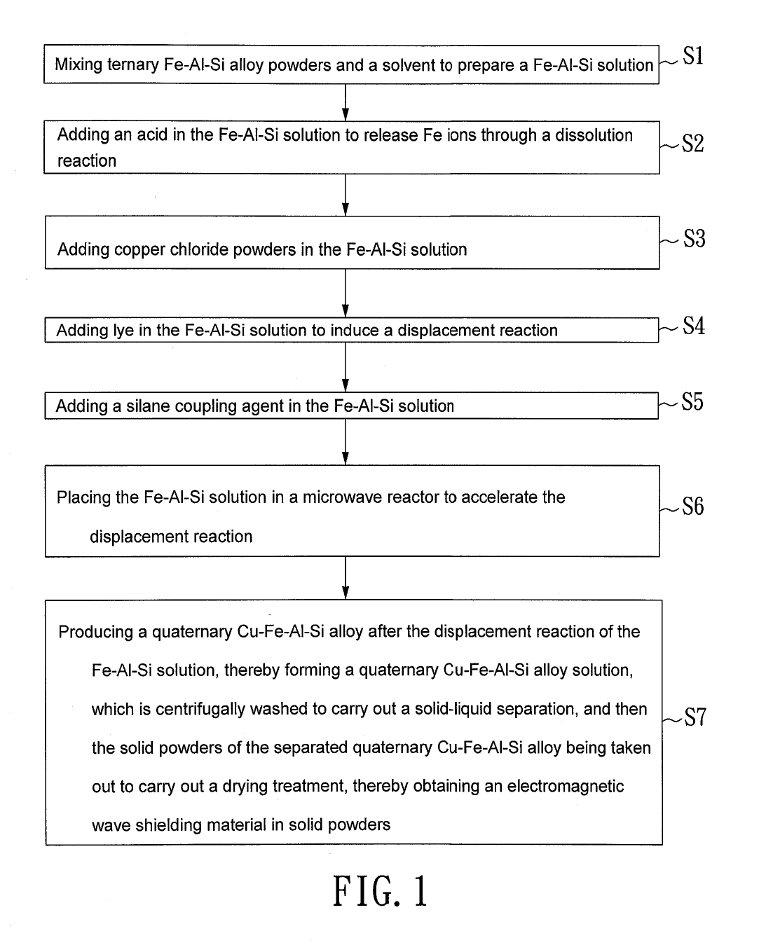

FIG. 1 is a flow diagram of a method for making an electromagnetic wave shielding material of the present invention.

### DETAILED DESCRIPTION

The embodiments of the present invention will be illustrated by specific examples below. Additional advantages and efficacy of the present invention will be readily apparent to those skilled in the art from the disclosure of the specification.

The flow diagram of the method for making electromagnetic wave shielding material of the present invention is shown in FIG. 1. The method comprises the following steps:

(a) Mix ternary Fe—Al—Si alloy powders and the solvent to prepare the Fe—Al—Si solution (S1), wherein the ternary Fe—Al—Si alloy powders may have a sheet-like, irregular-shaped or granular pattern and a particle size between 1 to 100 microns. The solvent may be pure water. The solid content of the Fe—Al—Si solution is from 60 to 100%.

(b) Add an acid in the Fe—Al—Si solution to release Fe ions through a dissolution reaction (S2). The principle is using the acid to dissolve the components of the Fe—Al—Si alloy surface to further induce the dissolution reaction that releases Fe ions. The weight ratio of the acid to the Fe—Al—Si solution is from 1:1 to 1:100. The acid added may be hydrochloric acid, sulfuric acid, nitric acid, phosphoric acid, or combinations thereof The concentration of the acid may be from 10% to 90%.

(c) Add copper chloride powders in the Fe—Al—Si solution (S3) to initiate a chemical reaction. The copper chloride powders may have monovalent copper, divalent copper, or combinations thereof The weight ratio of the copper chloride powders to the Fe—Al—Si solution is from 1:50 to 1:100.

(d) Add a lye in the Fe—Al—Si solution to induce a displacement reaction (S4), wherein the lye is ammonia, sodium hydroxide, or combinations thereof The pH value of the Fe—Al—Si solution added with the lye is in a range from 5 to 11.

(e) Add a silane coupling agent in the Fe—Al—Si solution (S5). The silane coupling agent acts as an interface modifier. The percentage of the silane coupling agent may be from 10% to 90%. The silane coupling agent is vinyltriethoxysilane (VTEO), 3-methacryloxy-propyl-trimethoxysilane (MEMO), or combinations thereof The formula of the silane coupling agent is:

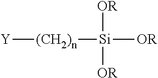

wherein R is CH₃, C₂H₅, or (CH₂)₂OCH₃, Y is an organofunctional group, and n is 0 or 3. The Y organofunctional group may be CH═CH₂ (vinyl group), H₂N (amino group), or CH₂═CHCH₃COO (methacryloxy group).

(f) Place the Fe—Al—Si solution in a microwave reactor to accelerate the displacement reaction (S6). The reaction time in the microwave reactor may be from 1 to 60 minutes. The power of the microwave reactor may be from 50 to 300 W.

(g) After the displacement reaction of the Fe—Al—Si solution, quaternary Cu—Fe—Al—Si alloy is produced, thereby forming a quaternary Cu—Fe—Al—Si alloy solution. The quaternary Cu—Fe—Al—Si alloy solution is centrifugally washed to carry out a solid-liquid separation, and then the solid powder of the separated quaternary Cu—Fe—Al—Si alloy is taken out to proceed with the drying treatment, thereby obtaining an electromagnetic wave shielding material in solid powders (S7). The step of centrifugal washing is processed by a centrifuge, and the step of drying treatment may be vacuum drying. The composition of the quaternary Cu—Fe—Al—Si alloy is as the following: 5-7% of Al, 5-7% of Si, 60-76% of Fe, and 10-30% of Cu.

The method for making an electromagnetic wave shielding material provided by the present invention uses a microwave reactor to perform the displacement reaction. In addition to substantially reduced production time, the pattern, composition, and particle size of the powders produced can be controlled by controlling the parameters of the microwave reactor and adjusting the parameters of the process, including the acid and lye added, the pH value, the percentage of the Fe—Al—Si powders, and the concentration of the copper chloride.

The present invention provides the method for making the electromagnetic wave shielding material. The preferred embodiment of the present invention comprised the following steps. First, 15 grams of the Fe—Al—Si powder were taken. The composition of the Fe—Al—Si powder was 7-9% of Al, 6-8% of Si, and 82-88% of Fe. The Fe—Al—Si powder was dissolved in 50 grams of concentrated hydrochloric acid and stirred to form the Fe—Al—Si solution. Thereafter, copper chloride was slowly poured into the Fe—Al—Si solution above, and then ammonia was added and stirred for 30-60 minutes to induce the displacement reaction of the Fe—Al—Si solution. Afterwards, 10 ml of 5% solution of the silane coupling agent were added in the Fe—Al—Si solution, and then the solution was placed in a microwave reactor to carry out the microwave reaction. The model name of the microwave reactor was Discover. The Fe—Al—Si solution was a black solution before the reaction was performed. The solution was poured into a 100 ml round bottomed flask, which was then placed in the microwave reactor and connected to a condensing tube for performing the microwave reaction. The conditions and parameters of the microwave reaction were described as the following. The power of the microwave was set at 150 W, the reaction temperature was 75° C., the reaction time was 5 minutes, and PowerMAX was on. After the reaction was completed, the microwave reactor cooled the reactants to 50° C. by the air in the air pump, and the quaternary Cu—Fe—Al—Si alloy solution was obtained. The function of PowerMAX was continuously cooling the reaction vessel by cooling gas under microwave irradiation. Since the traditional microwave reactor lowered or turned off the microwave power automatically when the temperature reached the set temperature, conventional thermo-chemical action might replace the chemical action of microwave heating. However, if the PowerMAX function was adopted, high-pressure air could be introduced continually to cool the reactants during the reaction. Therefore, it was definite that only the chemical action of microwave heating was performed during the reaction.

In the specific embodiment, in order to verify the quality of the quaternary Cu—Fe—Al—Si alloy manufactured through the microwave reaction, the present invention might further include the following step: putting the quaternary Cu—Fe—Al—Si alloy solution in a centrifugal cup to carry out four times of centrifugal washing, vacuum drying the solute at 80° C. for 5 hours, thereby forming dry powders of the quaternary Cu—Fe—Al—Si alloy.

According to the aforementioned, the method for making the electromagnetic wave shielding material provided by the present invention can easily make the quaternary Cu—Fe—Al—Si alloy powders having better electromagnetic wave shielding performance, as compared with the traditional technique. The present invention has the characteristics of rapid reaction and easy process, and is suitable for manufacturing the shielding material used in commercial 3C products that need mass production and cost control.

The embodiments described above are merely exemplary for illustrating the features and efficacy of the present invention and are not intended to limit the scope of the substantive technical content of the present invention. Various modifications and variations can be made to the embodiments described above by any person skilled in the art without departing from the spirit and scope of the present invention. Therefore, the scope of the present invention should be defined by the claims that follow.

What is claimed is:

1. A method for making an electromagnetic wave shielding material, comprising the steps of:
mixing ternary Fe—Al—Si alloy powders and a solvent to prepare a Fe—Al—Si solution;
adding an acid in the Fe—Al—Si solution to release Fe ions through a dissolution reaction;
adding copper chloride powders in the Fe—Al—Si solution;
adding a lye in the Fe—Al—Si solution to induce a displacement reaction;
adding a silane coupling agent in the Fe—Al—Si solution;
placing the Fe—Al—Si solution in a microwave reactor to accelerate the displacement reaction;
producing a quaternary Cu—Fe—Al—Si alloy after the displacement reaction of the Fe—Al—Si solution, thereby forming a quaternary Cu—Fe—Al—Si alloy solution, which proceeding with a solid-liquid separation and a drying treatment to obtain an electromagnetic wave shielding material in solid powders.

2. The method for making an electromagnetic wave shielding material according to claim 1, wherein the solvent is water.

3. The method for making an electromagnetic wave shielding material according to claim 1, wherein the solid content of the Fe—Al—Si solution is from 60% to 100%.

4. The method for making an electromagnetic wave shielding material according to claim 1, wherein the weight ratio of the acid to the Fe—Al—Si solution is from 1:1 to 1:100.

5. The method for making an electromagnetic wave shielding material according to claim 1, wherein the acid is hydrochloric acid, sulfuric acid, nitric acid, phosphoric acid, or combinations thereof, and the concentration of the acid is from 10% to 90%.

6. The method for making an electromagnetic wave shielding material according to claim 1, wherein the weight ratio of the copper chloride powders to the Fe—Al—Si solution is from 1:50 to 1:100.

7. The method for making an electromagnetic wave shielding material according to claim 1, wherein the reaction time in the microwave reactor is from 1 to 60 minutes.

8. The method for making an electromagnetic wave shielding material according to claim 1, wherein the power of the microwave reactor is from 50 to 300 W.

9. The method for making an electromagnetic wave shielding material according to claim 1, wherein the lye is ammonia, sodium hydroxide, or combinations thereof.

10. The method for making an electromagnetic wave shielding material according to claim 1, wherein the pH value of the Fe—Al—Si solution after the lye is added is in a range from 5 to 11.

11. The method for making an electromagnetic wave shielding material according to claim 1, wherein the percentage of the silane coupling agent added is from 10% to 90%.

12. The method for making an electromagnetic wave shielding material according to claim 1, wherein the drying treatment uses vacuum drying.

13. A method for making an electromagnetic wave shielding material, comprising the steps of:
mixing ternary Fe—Al—Si alloy powders and a solvent to prepare a Fe—Al—Si solution;
adding an acid in the Fe—Al—Si solution to release Fe ions through a dissolution reaction;
adding copper chloride powders in the Fe—Al—Si solution;
adding a lye in the Fe—Al—Si solution to induce a displacement reaction;
adding a silane coupling agent in the Fe—Al—Si solution;
placing the Fe—Al—Si solution in a microwave reactor to accelerate the displacement reaction;
producing a quaternary Cu—Fe—Al—Si alloy after the displacement reaction of the Fe—Al—Si solution, thereby forming a quaternary Cu—Fe—Al—Si alloy solution, which proceeding with a solid-liquid separation and a drying treatment to obtain an electromagnetic wave shielding material in solid powders;
wherein the composition of the quaternary Cu—Fe—Al—Si alloy is as the following: 5-7% of Al, 5-7% of Si, 60-76% of Fe, and 10-30% of Cu.

14. The method for making an electromagnetic wave shielding material according to claim 13, wherein the solvent is water.

15. The method for making an electromagnetic wave shielding material according to claim 13, wherein the solid content of the Fe—Al—Si solution is from 60% to 100%.

16. The method for making an electromagnetic wave shielding material according to claim 13, wherein the weight ratio of the acid to the Fe—Al—Si solution is from 1:1 to 1:100.

17. The method for making an electromagnetic wave shielding material according to claim 13, wherein the acid is hydrochloric acid, sulfuric acid, nitric acid, phosphoric acid, or combinations thereof, and the concentration of the acid is from 10% to 90%.

18. The method for making an electromagnetic wave shielding material according to claim 13, wherein the weight ratio of the copper chloride powders to the Fe—Al—Si solution is from 1:50 to 1:100.

19. The method for making an electromagnetic wave shielding material according to claim 13, wherein the reaction time in the microwave reactor is from 1 to 60 minutes.

20. The method for making an electromagnetic wave shielding material according to claim 13, wherein the power of the microwave reactor is from 50 to 300 W.

21. The method for making an electromagnetic wave shielding material according to claim 13, wherein the lye is ammonia, sodium hydroxide, or combinations thereof.

22. The method for making an electromagnetic wave shielding material according to claim 13, wherein the pH value of the Fe—Al—Si solution after the lye is added is in a range from 5 to 11.

23. The method for making an electromagnetic wave shielding material according to claim 13, wherein the percentage of the silane coupling agent added is from 10% to 90%.
